(19) United States
(12) Patent Application Publication
(10) Pub. No.: US 2013/0223035 A1
(43) Pub. Date: Aug. 29, 2013

(54) MOTHERBOARD

(71) Applicant: PEGATRON CORPORATION, (US)

(72) Inventors: Wei-Ting JHOU, Taipei City (TW); Shih-Yi YANG, Taipei City (TW)

(73) Assignee: PEGATRON CORPORATION, Taipei City (TW)

(21) Appl. No.: 13/708,768

(22) Filed: Dec. 7, 2012

(30) Foreign Application Priority Data
Feb. 29, 2012 (TW) 101203554

(51) Int. Cl. H05K 1/14

(52) U.S. Cl. CPC H05K 1/141
USPC 361/785; 361/784

(57) ABSTRACT

A motherboard is disclosed, which allows an expansion circuit board to be electrically connected to it. The motherboard includes a primary circuit board and an adapter component. The primary circuit board includes an expansion slot. The adapter component is connected to the expansion slot. The adapter component is used for being electrically connected to the expansion circuit board, such that the primary circuit board and the expansion circuit board can perform signal transmission via the adapter component. The expansion circuit board and the primary circuit board are not located on the same plane.

### BACKGROUND

1. Technology Field

The disclosure relates to a motherboard; more particularly, the disclosure relates to a motherboard which allows an expansion circuit board to be electrically connected to it.

2. Description of the Related Art

Generally speaking, in order to provide a user with a motherboard capable of upgrading or expanding its original functions, most conventional motherboards are equipped with multiple expansion slots. In order to make those expansion slots on the motherboard usable, it is necessary to lay out circuits to those expansion slots on the motherboard, such that each of the expansion slots can exchange signals with a central processing unit (CPU) on the motherboard. However, the space available for the circuit layout of those expansion slots is limited by the width of the motherboard, so the motherboard can be equipped with only a few expansion slots.

For example, a type of half-width motherboard used in a cloud server is currently applied in industry. The width of this type of motherboard is about 6.3 inches to 6.6 inches, so this type of motherboard cannot be equipped with many expansion slots. Commonly in the market, motherboards such as the HP SL390S or ASUS RS700D can support only one peripheral component interconnect express (PCI-E) expansion slot; motherboards such as the DELL C6100 can support one larger-scale PCI-E expansion slot and at most one more smaller-scale PCI-E expansion slot.

The CPUs of conventional motherboards are capable of supporting multiple PCI-E expansion slots; one CPU can support multiple external expansion cards (such as network cards, sound cards, or video capture cards) at the same time. However, since the abovementioned half-width motherboard is too narrow and thus has limited space for arranging the PCI-E expansion slots, the capacity of the CPU for supporting a number of expansion slots is wasted because the number of PCI-E expansion slots is not maximized.

### SUMMARY

It is an object of the present invention to provide a motherboard design capable of maximizing the number of expansion cards or components supported by a central processing unit on a motherboard.

To achieve the abovementioned objects, the motherboard of the present invention allows an expansion circuit board to be electrically connected to it. The motherboard comprises a primary circuit board and an adapter component. The primary circuit board comprises an expansion slot. The adapter component is connected to the expansion slot, and is used for being electrically connected to the expansion circuit board. The expansion circuit board and the primary circuit board are not located on the same plane.

According to a first embodiment of the present invention, the adapter component of the present invention comprises a first adapter circuit board and a second adapter circuit board. One end of the first adapter circuit board is plugged into the expansion slot, and the other end of the first adapter circuit board is connected to the second adapter circuit board in the form of one piece. The second adapter circuit board comprises a first expansion slot, wherein the first expansion slot allows installation of an expansion circuit board.

According to a second embodiment of the present invention, the adapter component of the present invention comprises a first adapter circuit board and a second adapter circuit board. The second adapter circuit board comprises a first expansion slot and a second expansion slot. One end of the first adapter circuit board is plugged into the expansion slot, and the other end of the first adapter circuit board is plugged into the second expansion slot. The first expansion slot allows the expansion circuit board to be plugged into it.

According to a third embodiment of the present invention, the adapter component of the present invention comprises a second adapter circuit board and a transmission cable line. The second adapter circuit board comprises a first expansion slot and a second expansion slot. One end of the transmission cable line is plugged into the expansion slot, and the other end of the transmission cable line is plugged into the second expansion slot. The first expansion slot allows the expansion circuit board to be plugged into it.

According to a fourth embodiment of the present invention, the adapter component of the present invention comprises a transmission cable line, and the expansion circuit board comprises a third expansion slot. One end of the transmission cable line is plugged into the expansion slot, and the other end of the transmission cable line is plugged into the third expansion slot.

Other objects, advantages, and novel features of the invention will become more apparent from the following detailed description when taken in conjunction with the accompanying drawings.

### BRIEF DESCRIPTION OF THE DRAWINGS

These and other objects and advantages of the present invention will become apparent from the following description of the accompanying drawings, which disclose several embodiments of the present invention. It is to be understood that the drawings are to be used for purposes of illustration only, and not as a definition of the invention.

In the drawings, wherein similar reference numerals denote similar elements throughout the several views:

FIG. 1 illustrates an exploded drawing of a motherboard according to a first embodiment of the present invention.

FIG. 2 illustrates an assembly drawing of the motherboard according to the first embodiment of the present invention.

FIG. 3 illustrates an exploded drawing of the motherboard according to a second embodiment of the present invention.

FIG. 4 illustrates an assembly drawing of the motherboard according to the second embodiment of the present invention.

FIG. 5 illustrates an exploded drawing of the motherboard according to a third embodiment of the present invention.

FIG. 6 illustrates an assembly drawing of the motherboard according to the third embodiment of the present invention.

FIG. 7 illustrates an exploded drawing of the motherboard according to a fourth embodiment of the present invention.

FIG. 8 illustrates an assembly drawing of the motherboard according to the fourth embodiment of the present invention.

### DETAILED DESCRIPTION OF THE PREFERRED EMBODIMENT

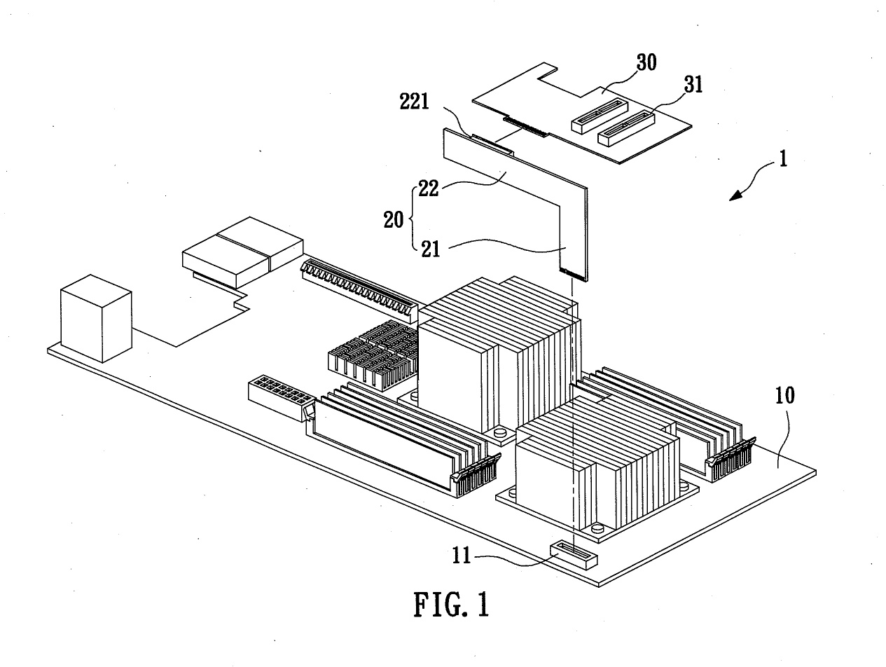

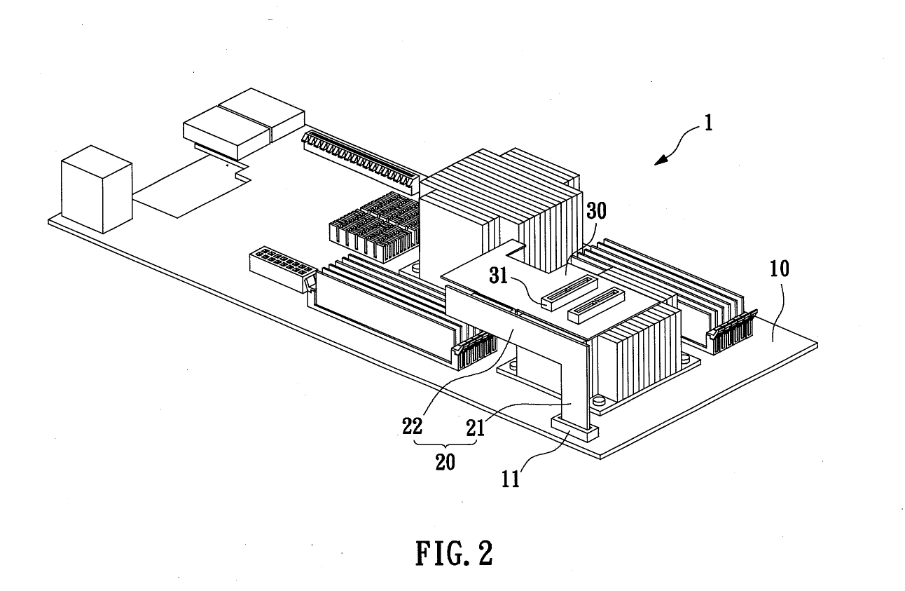

Please refer to both FIG. 1 and FIG. 2 regarding a motherboard according to a first embodiment of the present invention, wherein FIG. 1 illustrates an exploded drawing of the motherboard according to the first embodiment of the present invention, and FIG. 2 illustrates an assembly drawing of the motherboard according to the first embodiment of the present invention.

As shown in FIG. 1 and FIG. 2, in one embodiment of the present invention, the motherboard 1 of the present invention allows an expansion circuit board to be electrically connected to it. The motherboard 1 comprises a primary circuit board 10 and an adapter component 20. The primary circuit board 10 comprises an expansion slot 11. The expansion slot 11 is electrically connected to .a central processing unit (CPU) (not shown in figures) on the primary circuit board 10, such that the CPU can receive signals transmitted from the expansion slot 11 or can transmit various signals to the expansion slot 11. The expansion slot 11 can be an expansion slot conforming to a peripheral component interconnect express (PCI-E) standard, so as to connect to any expansion circuit board conforming to the PCI-E standard.

As shown in FIG. 1, in a first embodiment of the present invention, the adapter component 20 comprises a first adapter circuit board 21 and a second adapter circuit board 22. One end of the first adapter circuit board 21 is plugged into the expansion slot 11 such that it is perpendicular to the primary circuit board 10. The other end of the first adapter circuit board 21 is connected to the second adapter circuit board 22 in the form of one piece. The second adapter circuit board 22 comprises a first expansion slot 221. The first expansion slot 221 allows an expansion circuit board 30 to be plugged into it, such that the adapter component 20 is electrically connected to the expansion circuit board 30. When the expansion circuit board 30 is electrically connected to the adapter component 20, the expansion circuit board 30 and the primary circuit board 10 are not located on the same plane. In the first embodiment of the present invention, the expansion circuit board 30 comprises two third expansion slots 31, and the CPU on the primary circuit board 10 can perform signal transmission with each of the third expansion slots 31 via the adapter component 20, so as to increase the overall number of expansion slots of the motherboard 1. Please note that the expansion circuit board 30 of the present invention is not limited to being used for arranging expansion slots; the expansion circuit board 30 can also be equipped with other electronic components, such as USB connection ports, audio ports, or various kinds of I/O interfaces. Further, in the embodiment of the present invention, the expansion slot 11, the first expansion slot 221, the third expansion slot 31, and a to-be-described second expansion slot 222 of the motherboard 1 of the present invention are, but are not limited to, expansion slots conforming to the PCI-E standard.

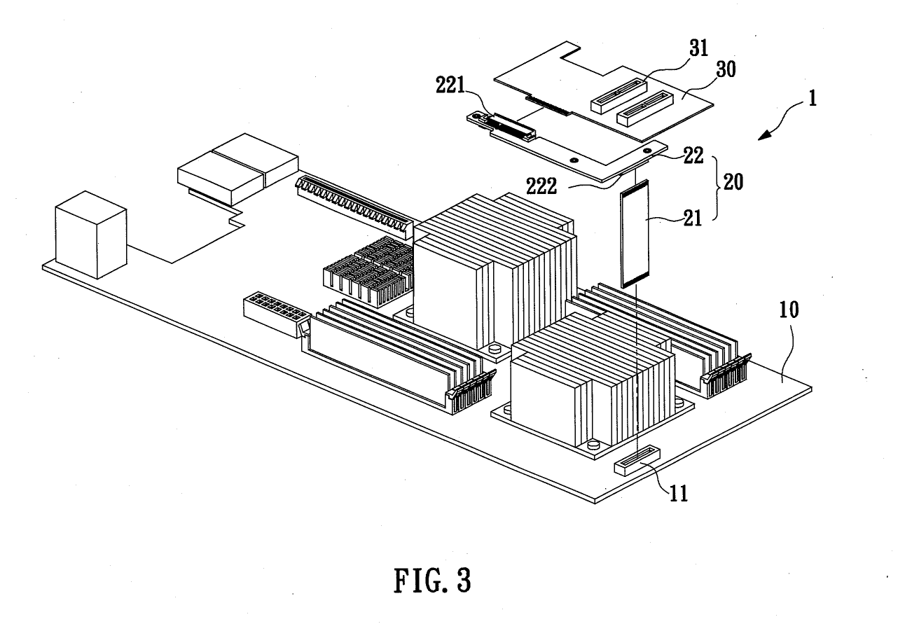

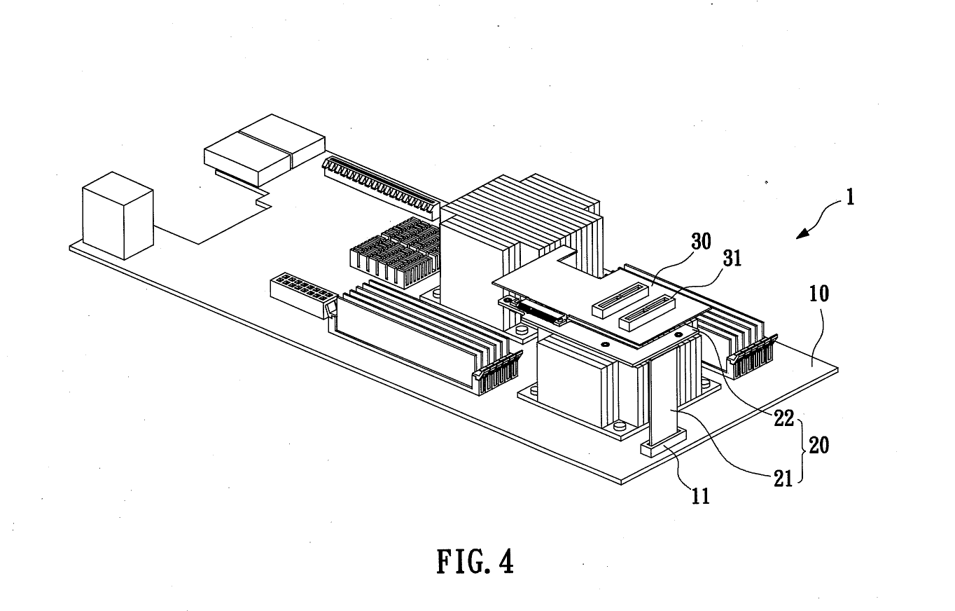

Please refer to FIG. 3 and FIG. 4 regarding the motherboard according to a second embodiment of the present invention, wherein FIG. 3 illustrates an exploded drawing of the motherboard according to the second embodiment of the present invention; and FIG. 4 illustrates an assembly drawing of the motherboard according to the second embodiment of the present invention.

As shown in FIG. 3 and FIG. 4, in the second embodiment of the present invention, the adapter component 20 also comprises the first adapter circuit board 21 and the second adapter circuit board 22. However, the difference between the second embodiment and the first embodiment is that in the second embodiment of the present invention, the second adapter circuit board 22 comprises the first expansion slot 221 and a second expansion slot 222. One end of the first adapter circuit board 21 is plugged into the expansion slot 11, and the other end of the first adapter circuit board 21 is plugged into the second expansion slot 222. The first expansion slot 221 allows the expansion circuit board 30 to be plugged into it, such that the adapter component 20 electronically connects to the expansion circuit board 30. Therefore, the second embodiment can achieve the same function as that of the abovementioned first embodiment. In the embodiment of the present invention, the second adapter circuit board 22 is in an L-shape, wherein the first expansion slot 221 is disposed to one end of the L-shape and the second expansion slot 222 is disposed to the other end of the L-shape; however the scope of the present invention is not limited to the above description.

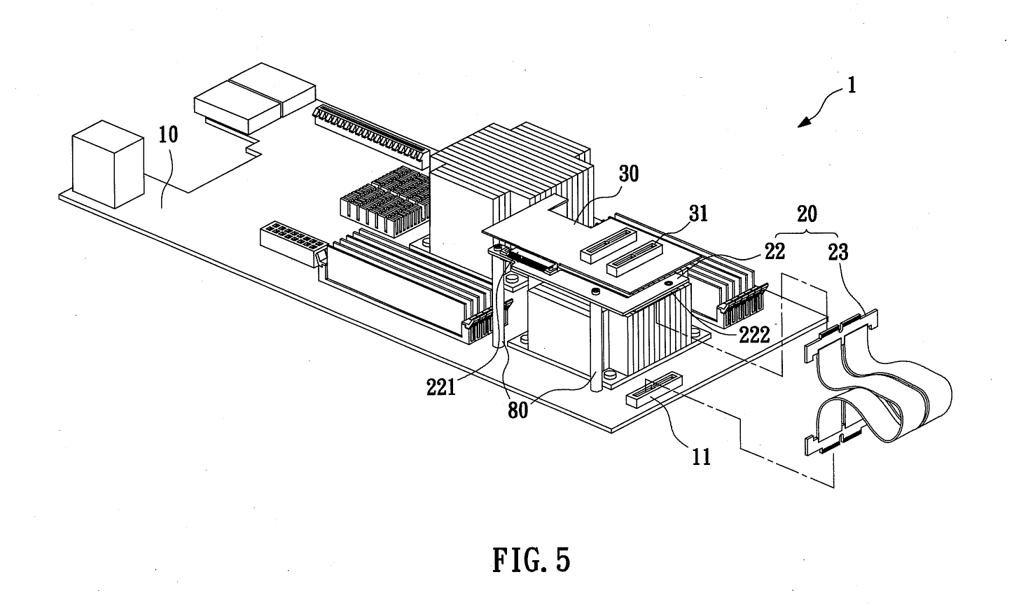

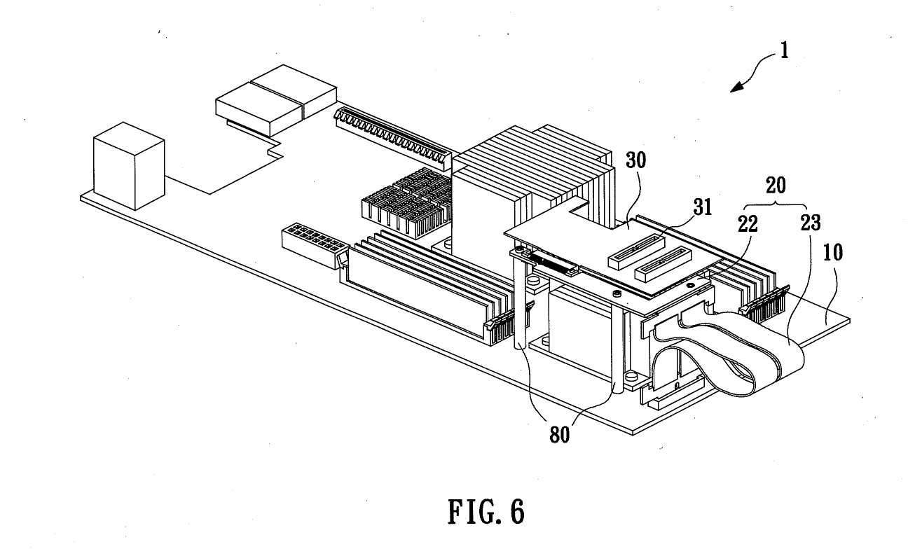

Please refer to FIG. 5 and FIG. 6 regarding the motherboard according to a third embodiment of the present invention, wherein FIG. 5 illustrates an exploded drawing of the motherboard according to the third embodiment of the present invention, and FIG. 6 illustrates an assembly drawing of the motherboard according to the third embodiment of the present invention.

As shown in FIG. 5, unlike in the abovementioned first and second embodiments, in the third embodiment of the present invention, a transmission cable line 23 is in place of the first adapter circuit board 21. In more detail, the adapter component 20 comprises the second adapter circuit board 22 and the transmission cable line 23. The second adapter circuit board 22 is mounted above the primary circuit board 10, and the second adapter circuit board 22 comprises the first expansion slot 221 and the second expansion 222. The first expansion slot 221 allows the expansion circuit board 30 to be plugged into it, such that the adapter component 20 electrically connects to the expansion circuit board 30. One end of the transmission cable line 23 is plugged into the expansion slot 11, and the other end of the transmission cable line 23 is plugged into the second expansion slot 222, so as to transmit various signals to the expansion circuit board 30 via the transmission cable line 23. In the third embodiment of the present invention, the first adapter circuit board 21 of the first embodiment and the second embodiment can be replaced by means of utilizing two fixing posts 80 to support and fix the second adapter circuit board 22 above the primary circuit board 10. However, in the third embodiment, the mechanism of fixing the second adapter circuit board 22 is not limited to the fixing posts 80 shown in FIG. 5.

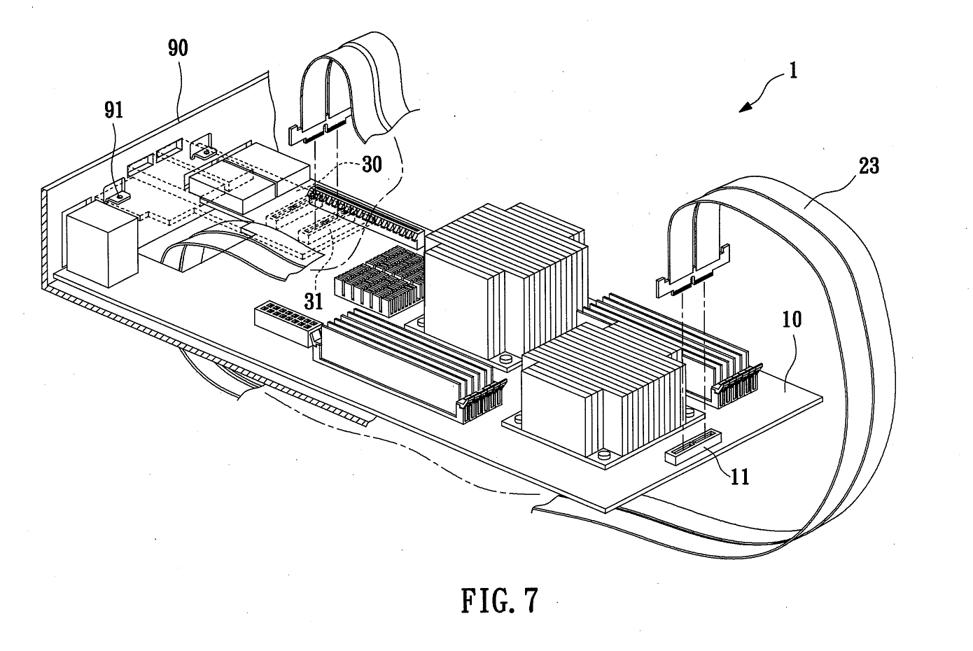

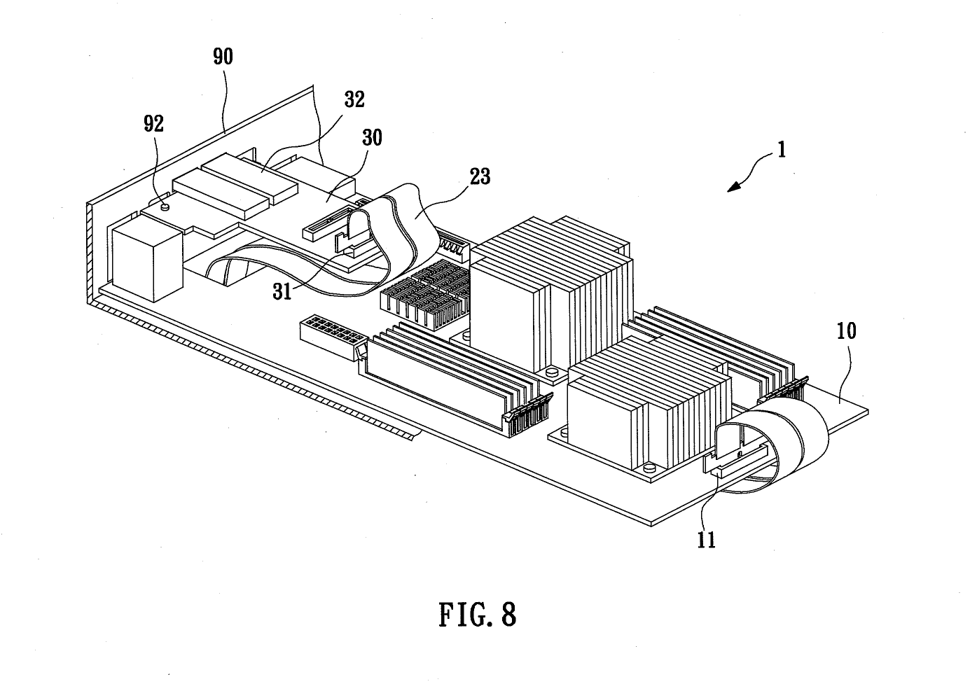

Please refer to FIG. 7 and FIG. 8 regarding the motherboard according to a fourth embodiment of the present invention, wherein FIG. 7 illustrates an exploded drawing of the motherboard according to the fourth embodiment of the present invention, and FIG. 8 illustrates an assembly drawing of the motherboard according to the fourth embodiment of the present invention.

As shown in FIG. 7, in the fourth embodiment of the present invention, unlike in the third embodiment, the utilization of the second adapter circuit board 22 is omitted, and the transmission cable line 23 is directly utilized as the only adapter component. In the fourth embodiment of the present invention, one end of the transmission cable line 23 is connected to the expansion slot 11, and the other end of the transmission cable line 23 is directly connected to the third expansion slot 31 on the expansion circuit board 30. Because the length limitation of the second adapter circuit board 22 in the third embodiment does not exist in the fourth embodiment, the expansion circuit board 30 can be arranged in a position farther from the expansion slot 11. As shown in FIG. 8, in order to provide a user with the expansion circuit board 30 equipped with an I/O interface (such as a USB connection port 32), the expansion circuit board 30 has to be arranged in a position closer to a casing 90 which carries the motherboard 1. In such a case that the expansion slot 11 of the primary circuit board 10 is too far from the casing 90, and the internal space of the casing 90 is limited such that the second adapter circuit board 22 is not large enough, the fourth embodiment, in which the transmission cable line 23 directly connects to both the expansion slot 11 and the third expansion slot 31 on the expansion circuit board 30, may be applied. Because the transmission cable line 23 is flexible, it does not need too much space, and thus the disadvantage that a circuit board made of hard materials occupies a certain amount of space can be solved. As shown in FIG. 7 and FIG. 8, in the fourth embodiment of the present invention, the expansion circuit board 30 can be mounted in the casing 90 by means of utilizing a screw 92 passing through a hole 91. Please note that the mechanism of mounting the expansion circuit board 30 is not limited to the embodiment illustrated in FIG. 8.

According to the improvement of the motherboard 1 of the present invention, the number of expansion slots or components which can be supported by the CPU of the primary circuit board 10 can be maximized by means of arranging the expansion circuit board 30 equipped with multiple components or expansion slots above or under the primary circuit board 10. For example, if one CPU can support usage for three expansion slots, but the primary circuit board 10 can be equipped with only one expansion slot due to its limited width, the present invention can provide an expansion circuit board 30 equipped with three expansion slots, and the expansion circuit board 30 can be connected with the expansion slot on the original primary circuit board 10, such that the CPU can exchange signals with the three expansion slots of the expansion circuit board 30 via the adapter component 20, thereby making the three expansion slots usable, and thus using the maximum number of expansion slots which can be supported by the CPU.

Although the present invention has been explained in relation to its preferred embodiments, it is to be understood that many other possible modifications and variations can be made without departing from the spirit and scope of the invention as hereinafter claimed.

1. A motherboard, allowing an expansion circuit board to be electrically connected to it, the motherboard comprising:
a primary circuit board, comprising an expansion slot; and
an adapter component, connected to the expansion slot, wherein the adapter component is used for being electrically connected to the expansion circuit board, and the expansion circuit board and the primary circuit board are not located on the same plane.

2. The motherboard as claimed in claim 1, wherein the adapter component comprises a first adapter circuit board and a second adapter circuit board, wherein one end of the first adapter circuit board is plugged into the expansion slot, the other end of the first adapter circuit board is connected to the second adapter circuit board in the form of one piece, the second adapter circuit board comprises a first expansion slot, and the first expansion slot allows the expansion circuit board to be plugged into it.

3. The motherboard as claimed in claim 1, wherein the adapter component comprises a first adapter circuit board and a second adapter circuit board, wherein the second adapter circuit board comprises a first expansion slot and a second expansion slot; one end of the first adapter circuit board is plugged into the expansion slot, the other end of the first adapter circuit board is plugged into the second expansion slot, and the first expansion slot allows the expansion circuit board to be plugged into it.

4. The motherboard as claimed in claim 1, wherein the adapter component comprises a second adapter circuit board and a transmission cable line, wherein the second adapter circuit board comprises a first expansion slot and a second expansion slot; one end of the transmission cable line is plugged into the expansion slot, the other end of the transmission cable line is plugged into the second expansion slot, and the first expansion slot allows the expansion circuit board to be plugged into it.

5. The motherboard as claimed in claim 3, wherein the second adapter circuit board is in an L-shape; the first expansion slot is disposed to one end of the L-shape, and the second expansion slot is disposed to the other end of the L-shape.

6. The motherboard as claimed in claim 1, wherein the adapter component comprises a transmission cable line, and the expansion circuit board comprises a third expansion slot; one end of the transmission cable line is plugged into the expansion slot, and the other end of the transmission cable line is plugged into the third expansion slot.

7. The motherboard as claimed in claim 1, wherein the expansion slot conforms to a peripheral component interconnect express (PCI-E) standard.

8. The motherboard as claimed in claim 4, wherein the second adapter circuit board is in an L-shape; the first expansion slot is disposed to one end of the L-shape, and the second expansion slot is disposed to the other end of the L-shape.
